(19) United States
(12) Patent Application Publication
(10) Pub. No.: US 2014/0191111 A1
(43) Pub. Date: Jul. 10, 2014

(54) ACCUMULATING OPTICAL DETECTOR WITH SHUTTER EMULATION

(71) Applicant: DCG Systems, Inc., Fremont, CA (US)

(72) Inventor: Herve Deslandes, Saint Martin d'Uriage (FR)

(73) Assignee: DCG Systems, Inc., Fremont, CA (US)

(21) Appl. No.: 14/097,117

(22) Filed: Dec. 4, 2013

Related U.S. Application Data
(60) Provisional application No. 61/735,510, filed on Dec. 10, 2012.

(51) Int. Cl. H01L 27/148; G01N 21/63; G01N 21/71; G01N 21/66

(52) U.S. Cl. CPC H01L 27/14806; G01N 21/66; G01N 21/63; G01N 21/71
USPC 250/208.1; 257/225

(57) ABSTRACT

An optical detector is disclosed, having a plurality of detector cells, each detector cell comprising a light sensor, a charge accumulator, and a switch interposed between the light sensor and the charge accumulator; wherein the light sensor produces electrical current when illuminated by electromagnetic radiation, the charge accumulator accumulate electric charge when receiving the electrical current generated by the light sensor, and the switch is configured to controllably electrically isolate or connect the charge accumulator to light sensor, such that the charge accumulator accumulates charge only when electrically connected by the switch to the light sensor.

### RELATED APPLICATION

This Application claims priority benefit from U.S. Provisional Application No. 61/735,510, filed on Dec. 10, 2012, the disclosure of which is incorporated herein by reference in its entirety.

### STATEMENT REGARDING FEDERALLY SPONSORED RESEARCH OR DEVELOPMENT

This invention is based upon work supported by the Office of the Director of National Intelligence (ODNI), Intelligence Advanced Research Projects Activity (IARPA), via Air Force Research Laboratory (AFRL) contract number FA8650-11-C-7105. The ideas and conclusions contained herein are those of the inventors and should not be interpreted as necessarily having the official endorsements, either expressed or implied, of ODNI, IARPA, AFRL, or the U.S. Government.

### BACKGROUND

1. Field

The present application belongs to the field of imaging of transient phenomena and also to repeated imaging of faint light, such as during semiconductor photon emission microscopy.

2. Related Art

Imaging of faint light sources occurs in many fields, including astronomy and Photon Emission Microscopy. Sometimes the goal is to create a projected image, and sometimes to create a spectrographic analysis.

In the semiconductor industry, Photon Emission Microscopy (PEM) is commonly used for circuit diagnostics and analyses of LSI (Large-Scale Integration) devices (chips). The premise of PEM is that individual logic gates within a LSI circuit emit “Hot Carrier” (HC) photons when switching on/off states. These photons are generally in the Infrared (IR) part of the spectrum, and since silicon is transparent at these wavelengths, it is possible to observe the circuit (Device Under Test, or DUT) in action. Since silicon is transparent to some IR wavelength, it is sometimes possibly to make the observation through the back side (the substrate side, opposite to the metal layer side) of the DUT.

During observation by the microscope (FIG. 1), the DUT [10] is stimulated by an electronic tester [11], which causes it to become active and change internal states. The tester essentially emulates the rest of the electronic system within the likes of which the chip is designed to be embedded, using pre-programmed test signal sequences known as test vectors. Each test vector causes changes in the state of gates in the DUT, and for diagnostics, test vectors are typically repeated numerous times. The detector array [12] observes the DUT through an optical system [13], and is typically located in a thermal enclosure [14] and kept below room temperature.

Since HC emissions can be very faint, observation times vary from seconds to many minutes. To capture these faint emissions, special detector arrays are used, where each pixel comprises both a light sensor and a charge accumulator. The light sensor produces electric current in proportion to the instantaneous level of illumination incident upon it, and the charge accumulator collects this current over the entire observation time. At the end of the observation window, the charge accumulator is read electronically through a read-out circuit. The combined effect is analogous to the behavior of photochemical film, in that the final reading corresponds to the total illumination throughout the exposure, integrated over the exposure time.

Detector arrays such as these are common art. The sensor elements are fabricated using semiconductor technologies such as silicon (MOS), InGaAs, or HgCdTe (MCT). The charge accumulators are typically capacitors (either intrinsic or external), and can be fabricated using the same technology as the sensor (such as in MOS CCD devices) or using a different semiconductor technology, in which case the complete detector array is comprised of two interconnected (typically physically sandwiched) ICs, forming a hybrid technology detector. In such hybrid detector arrays, there is sometimes a connector IC situated between the sensor and the capacitor array, whose purpose is simply to form the connections between each sensor cell and its corresponding capacitor cell and electronics.

FIG. 2 shows a schematic diagram of a single pixel within the detector array, consisting of a light detector [20] exposed to light [22], and a capacitor [21], connected so that the output current of the light sensor accumulates in the capacitor throughout the exposure time. The readout circuit (not shown), which might consist of a charge amplifier or similar device, is connected in parallel to the capacitor. The detector array is formed of a two-dimensional array of light detectors connected to a two dimensional array of charge accumulators, or capacitors.

When observing a VLSI circuit, HC emissions occur only during short time windows (in the order of tens of picoseconds), and those times can be known in advance based on the tester's test vectors. The number of such emission windows within a single observation period can be very high, even though the combined length of the emission windows is only a small fraction of the total observation period. The requirement for a long total observation period is therefore caused by two factors—the faintness of the emissions, and their scarcity over time.

Different types of noise, affects the detector over the entire observation time and so accumulates disproportionately in comparison with the HC emissions that constitute the desired signal. In other words, while during the actual HC emission, and even during the emission window, the signal-to-noise (SNR) ratio is high, it is watered down over the long observation time.

Specifically, in certain circuits leakage emissions have similar wavelengths to those of HC emissions. HC emissions only occur during the short time of a switching event when the transistor changes state (ON to OFF or vice versa) yet the leakage emissions occur continually when the transistor is in the ON state for a n-FET or an OFF state for a p-FET. Certain time windows in a test loop may need to be examined with PEM and those time windows can be known in advance based on the test vectors.

In principle, one way to increase the signal to noise ratio (SNR) is to place a shutter in front of the detector, and open the shutter only during the emission windows, multiple times within the observation period. However, in many applications this is not a practical solution. The emission windows might be too short (e.g. tens of picoseconds), the shutter might have an infra-red signature of its own, or might be too complicated to operate while cold.

Taking multiple electronic readings of the charge accumulators (i.e. multiple observations) is often not practical either, since the readout process either takes too long, or introduces too much noise before a sufficiently robust signal has been accumulated in them.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Described herein are aspects of an improved detector array in which the sensing and accumulation functions are enabled separately and operated independently of each other, controlled by different command circuits. An added switching circuit is interposed between the sensor and capacitor, the switching circuit capable of isolating the capacitor from the sensor, so that during this isolation the capacitor retains its charge irrespective of what the sensor is seeing.

The purpose of this separation and added circuitry is to, in effect, emulate the function of a high-quality shutter. This ability enables very accurate timing of the exposure, and also enables non-continuous accumulation of light detection during an observation.

This disclosure refers to the timing signal that controls the switching circuit as the “shutter signal”, even though the system does not in fact have a shutter in it, since it essentially emulates, (in functional way only), a perfect shutter. The detector and microscope are therefore referred to herein as “shutter enabled”.

Also described herein are aspects of a VLSI emission microscope that comprises such an improved detector array, and controls the timing of the emission windows based on the test vectors produced by the tester circuitry.

The utility of the invention therefore includes the ability to reject noise or other unwanted optical input that occurs during certain time periods within the observation window, such as rejecting the leakage emissions and capturing the switching emissions in PEM, as described above. Other utility of the invention includes not collecting light from part of the test sequence that would mask the emission of some more interesting part of the test sequence. Other utility includes test and debug, where one can see where inside the IC each part of the test sequence propagates or fails.

Applications where it is desired to accumulate discrete non-continuous windows into a single exposure extend well beyond VLSI microscopy. For example, in life science one might want to repeatedly look at faint emissions from a biological organ, but only in the microsecond that follows certain neural activity. For example, in astronomy, where exposure times can last hours, one might want to exclude certain time windows from a the exposure, since those time windows are known or predicted to have high noise levels. (e.g. an airplane or satellite are about to cross the field of view).

According to one aspect, an optical detector is disclosed, having a plurality of detector cells, each detector cell comprising a light sensor, a charge accumulator, and a switch interposed between the light sensor and the charge accumulator; wherein the light sensor produces electrical current when illuminated by electromagnetic radiation, the charge accumulator accumulate electric charge when receiving the electrical current generated by the light sensor, and the switch is configured to controllably electrically isolate or connect the charge accumulator to light sensor, such that the charge accumulator accumulates charge only when electrically connected by the switch to the light sensor.

According to another aspect, a system for testing samples is disclosed, comprising: an excitation source applying a series of excitations pulses to the sample; an optical sensor situated to image a desired area of the sample; a controller providing clock signal to the excitation source and a sync signal to the optical sensor; wherein the optical sensor comprises: an array of light sensors, an array of charge accumulators, and a switching circuit interposed between the array of light sensors and the array of charge accumulators; wherein the array of light sensors produces electrical current when illuminated by electromagnetic radiation, the array of charge accumulators accumulates electric charge when receiving the electrical current generated by the array of light sensors, and the switching circuit electrically isolates or connects the array of charge accumulators to the array of light sensors according to the sync signal.

According to yet another aspect, a method for examining a sample is disclosed, comprising: applying a series of excitations pulses to the sample; operating a light sensor array to image a selected area of the sample; energizing a switching array so as to connect the light sensor array to a capacitor array during selected time windows at time periods between the series of excitation pulses; and, using charge from the capacitor array to generate images of the sample.

Further advantages, features and potential applications of the present invention may be gathered from the description which follows, in conjunction with the embodiments illustrated in the drawings.

### DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1: Prior Art—A standard detector array within a PEM system;

FIG. 2: Prior Art—Schematic diagram of a single array element;

FIG. 3: Schematic diagram of a shutter-enabled single array element;

FIG. 4: Switching element array between sensor and capacitor arrays;

FIG. 5: A shutter-enabled detector array within a PEM system;

FIG. 6: A shutter-enabled detector array within a strobe photography system;

FIG. 7: A shutter-enabled detector array within a telescope system;

FIG. 8: A shutter-enabled detector array within a spectrograph system;

FIG. 9: Timing diagram illustrating the use of the shutter signal; and,

FIG. 10: A testing system utilizing a shutter-enabled detector array according to one embodiment.

FIG. 11 is a schematic illustrating a system for performing lock-in thermography (LIT) and which may incorporate the sensor according to embodiments of the invention.

### DETAILED DESCRIPTION

Described herein are aspects of an improved detector array in which the sensing and accumulation functions are enabled separately and operated independently of each other, and controlled by different command circuits. An added switching circuit is interposed between the sensor and capacitor arrays, the circuit capable of isolating the capacitors from the sensors, so that during this isolation the capacitors retain charge irrespective of what the sensor is seeing.

Note that there's a very significant difference between using the shutter signal multiple times and reading the detector multiple times, since in the latter case the readout electronics operate multiple times, even as the capacitors have accumulated only a small amount of data per reading, whereas in the former case the capacitors are allowed to accumulate charge over multiple time windows, and are read only once.

FIG. 3 depicts a functional diagram of an individual pixel element under an embodiment of this invention. The pixel element comprises a light sensitive detector element [30] exposed to light [34], connected electrically to a capacitor [31]. A switching element [32] is located between them, so that based on the shutter signal line [33], the capacitor can be either connected to the light detector, or isolated therefrom. When the capacitor is connected to the light detector, it continually receives the electrical signal from the light detector so as to accumulate charge. When the capacitor is isolated from the light detector, it retains its charge, but does not accumulate any further charge, regardless of the light exposure of the light sensor.

In some embodiments, the switching element may be a transistor or transistors array, but other types of switching elements can also be used. In one embodiment of the invention, suitable for hybrid technology detector arrays, an array of switching circuits (For example CMOS transistors) is inserted between the sensor array and the capacitor array.

FIG. 4 depicts such an embodiment. A light sensor array [41] is exposed to incoming light [40]. A capacitor array [43], which normally would have been connected directly to the sensor array, is now connected to it through a switching array [42]. A shutter command line [45] is connected to the switching array, and the read-out circuits [44], same as in the standard detector, are connected to the capacitor array [43]. The switching array can be a modification of the connector IC in a standard hybrid detector array. In this embodiment, a single shutter signal line controls all of the switching elements, but it is also possible to have multiple lines, each controlling a subset of the switching elements.

Specifically, in some embodiments, in order to reduce power consumption and heat generation by the switching elements, only a portion of the switching array is comprised of active switching elements, whereas the rest of the array is comprised of passive pass-through connections. For example, the accumulator array may be divided into multiple sub-arrays, and each sub-array is connected to one switching element.

In one embodiment, a detector array is modified by adding a switching element into each pixel, connected electrically between the sensor and accumulator elements. This embodiment is suitable to MOS CCDs in which the sensor and capacitor elements are formed on the same substrate.

In both of the above embodiments, for each pixel it becomes possible for the capacitor to be isolated from the light detector, as controlled by an external command signal.

Also described herein are aspects of a VLSI emission microscope that comprises such an improved detector array, and controls the timing of the emission windows using a trigger signal calculated based on the test vectors produced by the tester circuitry.

The utility of the invention therefore includes the ability to reject noise or other unwanted optical input that occurs during certain time periods within the observation window, such as rejecting the leakage emissions and capturing the switching emissions in PEM, as described above. Other utility of the invention includes not collecting light from part of the test sequence that would mask the emission of some more interesting part of the test sequence. Other utility includes test and debug of a microchip, wherein one can see where inside the IC each part of the test sequence propagates or fails to propagate.

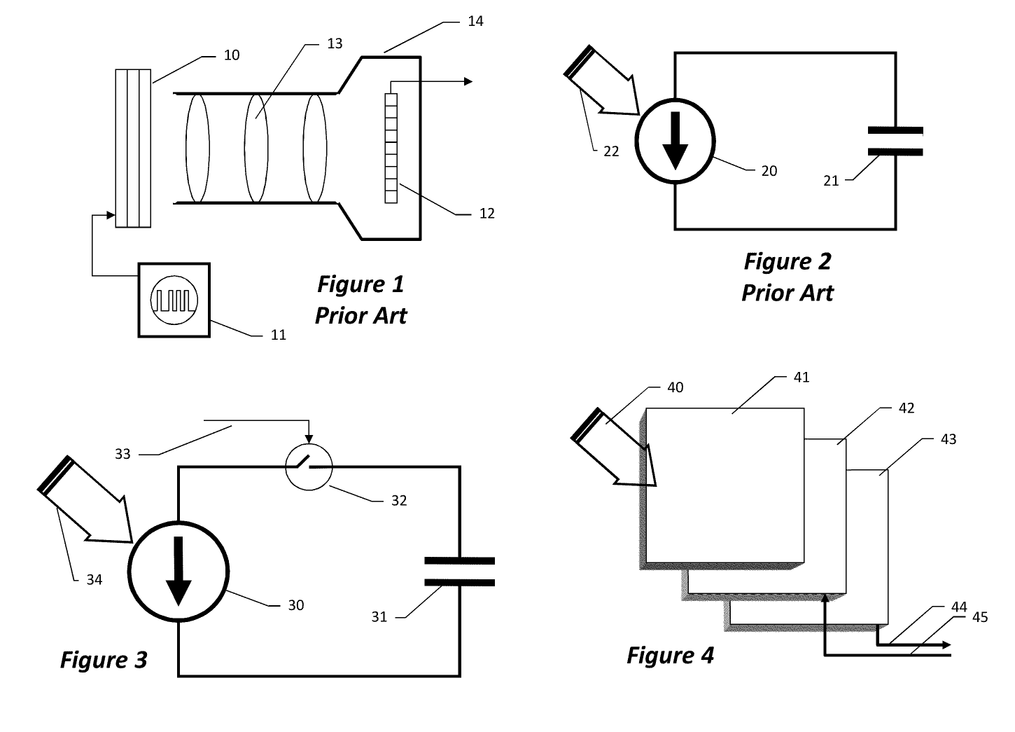

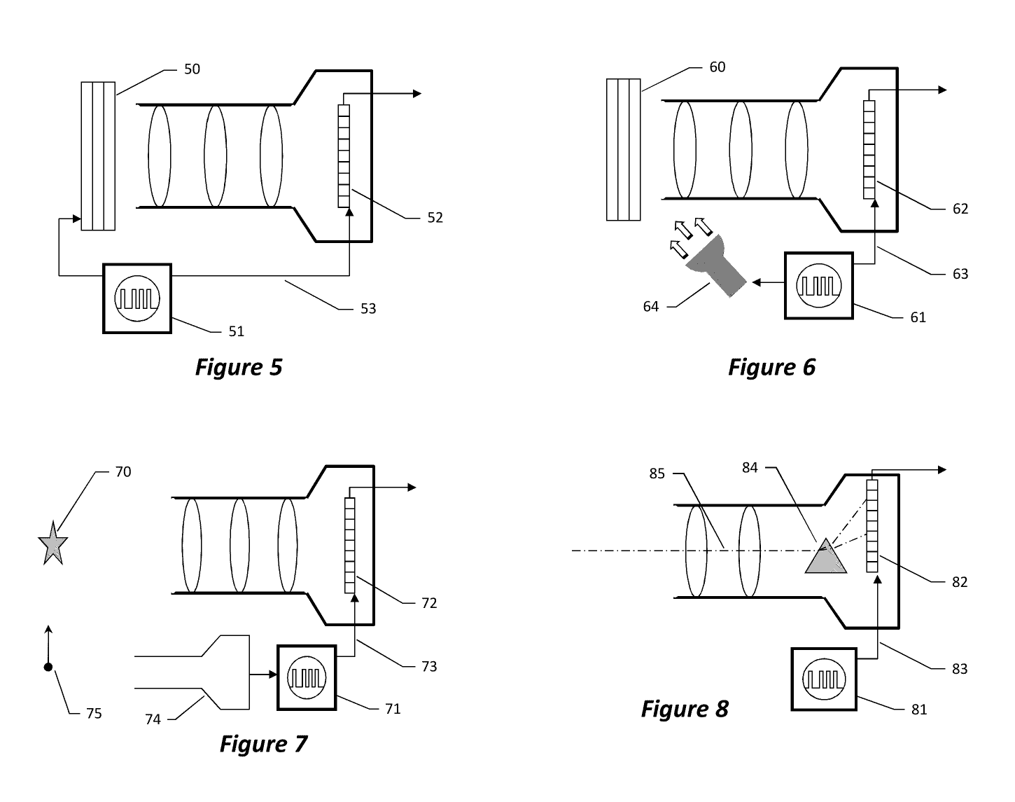

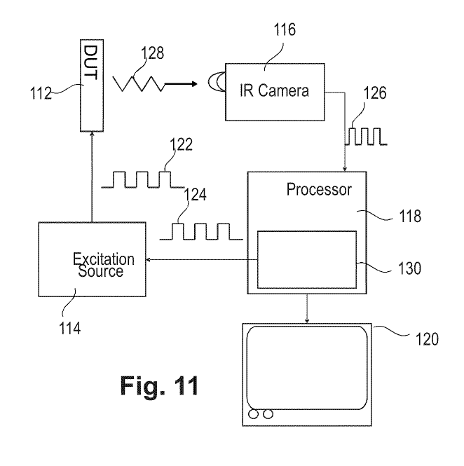

FIG. 5 depicts an embodiment of a VLSI emission microscopy system, based on the one shown in FIG. 1. An extra shutter signal line [53] now connects the tester [51] to the detector [52], to synchronize the observation windows with the test vectors that are sent to the DUT [50]. A more detailed example of such a system is provided in FIG. 10, which will be described below.

Applications where it is desired to accumulate discrete non-continuous windows into a single exposure extend well beyond VLSI microscopy.

For example, in life science one might want to repeatedly look at faint emissions from a biological organ, but only in the microsecond that follows certain neural activity or an illumination from a strobe light. FIG. 6 shows such an embodiment. The detector array (62) is looking at a specimen (60) through an optical system. A controller (61) controls a strobe light (64). Normally, the detector would be swamped by reflected light from the strobe. However, the faint desired emission occurs only within a few microseconds after the strobe. In this embodiment, the controller uses the shutter signal to enable light accumulation in the right window, thus ignoring the reflected light. A regular shutter cannot be controlled to microsecond precision.

For example, in astronomy, where exposure times can last hours, one might want to exclude certain time windows from a the exposure, since those time windows are known or predicted to have high noise levels. (e.g. an airplane or satellite are about to cross the field of view). FIG. 7 shows an embodiment of a telescope in which a detector array (72) is observing a target [70] through an optical system. A controller [71] is connected to a wider angle optical system [74] which detects a satellite [75] just outside the field of view of the main optical system and heading towards it. The controller [71] uses the shutter signal line [73] to temporarily suspend the accumulation of light from the target [70] until the satellite leaves the field of view.

In another embodiment, the function of the wide angle optics is replaced by additional detector cells on the periphery of the main detector [70]. These peripheral “guard” cells are not shuttered with the rest of the array, so that they can continue to work even when light accumulation is suspended, and be able to detect when the interfering source leaves the field of view.

FIG. 8 shows an embodiment of this invention when a one-dimensional detector array [82] is used in conjunction with a prism [84] in order to implement a spectrometer. As in other embodiments, the shutter signal [83] from a controller [81] allows the selective accumulation of optical signal, “skipping over” time periods of no interest or time periods containing high levels of unwanted noise.

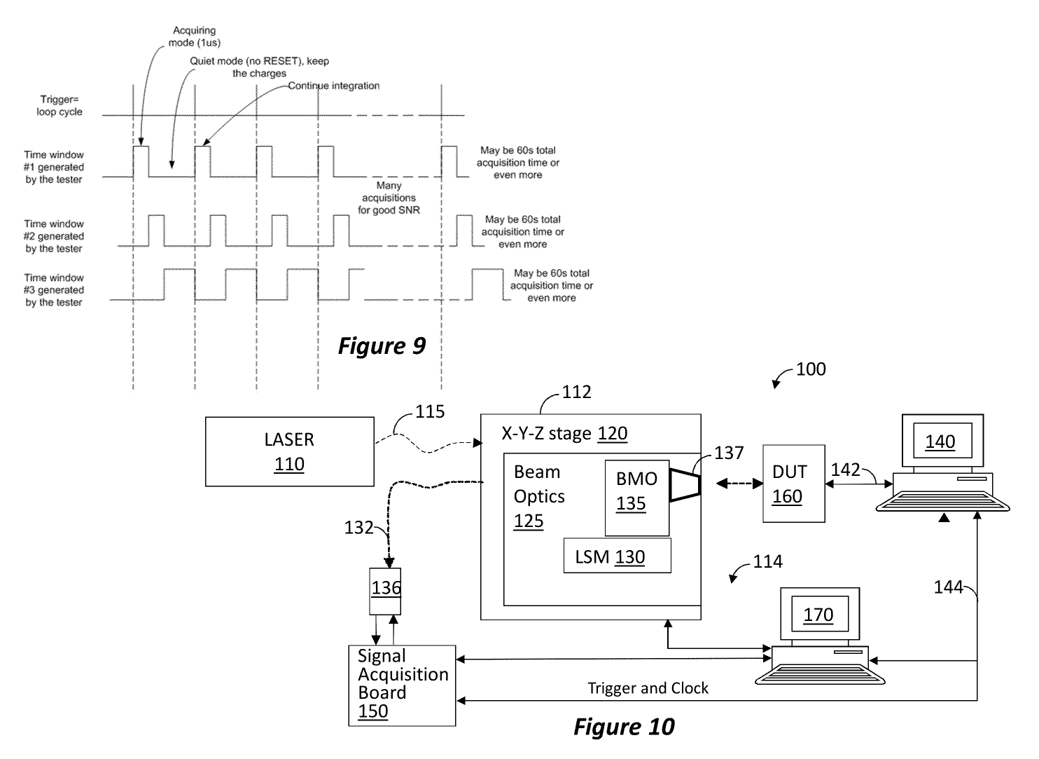

FIG. 9 illustrates the relative timings of shutter signals that can be generated by the tester, relative to the pulse that marks the beginning of a test vector. The example shows the concept of separating the full test cycle into 3 different time periods. Each period is repeated many times until sufficient SNR is obtained and at the end of the full process we will get 3 images with each image showing the emission map of the DUT activity corresponding for each specific part of the test sequence. So besides the classical obvious X,Y information we get with each image, we will have a third component which is the time t (time window #1, #2 and #3). The smallest time resolution we can get is driven by the speed and performance of the readout circuit of the FPA.

A classical PEM camera would have acquired only 1 image showing the full activity of the DUT during the test cycle.

In another embodiment, when the excitation signal is repetitive, and the response of the DUT is deterministic, it is possible for the controller to discover the timing relationship between the excitation vector and the DUT's response emission, thus finding the timing for the optimal exposure window. To achieve that, the controller analyses the output using several different exposure window timings and notes the signal observed in each window. It is then possible the further refine the windows by any number of logic algorithms (e.g. further sub-dividing the window in which the best signal was observed, or reconstructing the entire emission signal by treating the exposure windows as signal sampling points) and arrive at an optimal exposure window for the observation of that signal. Since the signal is repetitive, this is analogous to achieving phase lock-in between the measurement timing and the observed signal.

FIG. 10 is a general schematic depicting major components of a system architecture, 100, for testing microchips (DUT). In FIG. 10, dashed arrows represent optical path, while solid arrows represent electronic signal path. The optical paths represented by dashed lines are generally made using fiber optic cables. Probing system 100 comprises a laser source 110, which may be used for imaging or for testing of the DUT. When used for imaging of the DUT, the laser may be a simple continuous wave (CW) laser. When used for testing the DUT, the laser may be a CW laser, a pulsed laser, a mode-locked laser (MLL), etc., depending on the test performed. The system also includes an optical bench 112 and data acquisition and analysis apparatus 114. The optical bench 112 includes provisions for mounting the DUT 160 and includes beam optics 125. The beam optics 125 may include various elements to shape the beam, generally shown as beam manipulation optics, BMO 135, and elements for pointing and/or scanning the beam over the DUT, such as a laser scanning microscope, LSM 130. Light is focused and collected by the objective lens 137. A computer 140 or other controller device may be used to provide power and/or test signals, 142, to the DUT 160, and may provides trigger and clock signals 144 to the analysis apparatus 114 and optionally also to the laser source 110 (when an MLL is used). The analysis apparatus, 114, includes workstation 170, which controls as well as receives, processes, and displays data from the signal acquisition board 150 and the optical bench 112.

In operation, computer 140, which may be a conventional ATE (Automated Testing Equipment, also known as Automated Testing and Evaluation), generates test vectors that are electrically fed to the DUT. The ATE also sends sync signal (trigger and clock) to the analysis apparatus 114 and, in this particular example, also to the signal acquisition board 150. The beam optics 125 is then used to collect emissions from various positions on the DUT. The emissions are detected by photo sensor 136, which converts it into an analog signal. The analog signal is acquired by the signal acquisition board 150 and is fed to computer 170. By correlating the timeline of the waveform to that of the ATE, the response of the DUT can be analyzed.

In this particular example, the photo sensor 136 is constructed according to the embodiments illustrated herein, wherein a switching array is interposed between the light sensor array and the charge accumulation array. The switching array is controlled using signals from the signal acquisition board 150, corresponding to the trigger and clock signals 144. Thus, analog signal from the light sensor array passes to the charge accumulation array only when the switching array receives an “on” command signal, e.g., from the signal acquisition board 150 or the computer 170.

FIG. 11 is a schematic illustrating a system for performing lock-in thermography (LIT) and which may incorporate the sensor according to embodiments of the invention. A device under test (DUT) 112 is stimulated by excitation signal 122 at a lock-in frequency generated by excitation source 114. The lock-in frequency of the excitation signal is set by a central processing unit 118. While generally thermography may be performed using sinusoidal signal, since the DUT is a digital device, excitation signal 122 is an electrical rectangular or square wave signal designed to turn on and off various active elements, e.g., transistors, within the DUT. In both rectangular and square wave signals the amplitude alternates instantaneously between fixed maximum and minimum values, such that the frequency is the number of transitions per period, e.g., number of transitions per second. Thus, in essence the test signal 122 can be considered as a train of pulses at a given frequency.

A sync signal 124 is output from the central processing unit 118 and sent to the excitation source 114. The simplest way is to set the sync signal 124 at the desired lock-in frequency, although it may be set to a different frequency, so long as provisions are made to enable excitation source 114 to generate the excitation signal 122 at the desired lock-in frequency using the sync signal 124. As the excitation signals cause currents to flow in the DUT 112, anomalies inside the DUT 112 cause local hot spots. The heat from the hot spots then propagates inside the DUT 112 until it reaches the surface of the DUT 112, which faces IR camera 116. The IR camera may be a two-dimensional array sensor according to the embodiments described herein. Then heat rays 128 outputted from the surface of the DUT 112 to IR camera 116 are used to take a series of IR images of surface of the DUT and to output image signals 126 to the central processing unit 118 including a processor 130. The frame rate of camera 116 is usually selected taking into account the lock-in frequency. In case of a 2-channel IR camera, the frame rate of the camera is 4-times the lock-in frequency. With the setup of FIG. 11, an identification of a hot spot's spatial and depth localization within the DUT 112 is possible. The processor 130 of the setup of FIG. 11 is configured to carry out the processing required in the invention as described below.

In the embodiment of FIG. 11, after each excitation signal, the light sensor array of IR camera continuously senses the radiation 128 and outputs a corresponding analog signal. However, the analog signal output from the light sensor array is “sampled” by periodically sending “on” and “off” command signals to the switching array, such that charge is accumulating by the capacitors array only during the “on” time of the switching array. Thus, for each period that follows an excitation pulse, a series of IR images is obtained.

With slight modifications, the embodiment of FIG. 11 can also be implemented for LIT of inactive samples. For example, the quality of a weld in a metallic part can be investigated or the voids in a cast material can be identified. In such examples, the excitation source is replaced by a heat excitation source, e.g., a high intensity laser illuminating a desired area of the sample, which now replaced the DUT. The excitation source heats us the desired area, and the heat begins to spread throughout the sample, up to its surface. However, voids and other defects interfere with the normal heat propagation within the sample. Using the sensor described herein, a series of IR images of the desired area are taken and compared to similar images taken from a sample having no defects or voids. The comparison is used to identify defective parts.

As can be seen from the above description, a method of operation is provided, wherein an excitation signal is applied to a sample under investigation. During a set period following the excitation signal, a series of switching commands is applied to a switching circuit that is interposed between a light sensor array and a charge accumulation array. The charge accumulated by the charge accumulation array may be sampled after each switching command or at the end of the set period.

While the invention has been described with reference to particular embodiments thereof, it is not limited to those embodiments. Specifically, various variations and modifications may be implemented by those of ordinary skill in the art without departing from the invention's spirit and scope, as defined by the appended claims.

What is claimed is:

1. An optical detector, comprising:
a plurality of detector cells, each detector cell comprising a light sensor, a charge accumulator, and a switch interposed between the light sensor and the charge accumulator;
wherein the light sensor produces electrical current when illuminated by electromagnetic radiation, the charge accumulator accumulate electric charge when receiving the electrical current generated by the light sensor, and the switch is configured to controllably electrically isolate or connect the charge accumulator to light sensor, such that the charge accumulator accumulates charge only when electrically connected by the switch to the light sensor.

2. The optical detector of claim 1, wherein said light sensor is a MOS device.

3. The optical detector of claim 1, wherein said light sensor is a InGaAs device.

4. The optical detector of claim 1, wherein said light sensor is an HgCdTe device.

5. The optical detector of claim 1, wherein said light sensor is sensitive to electromagnetic spectrum at wavelengths between 1 um and 3 um.

6. The optical detector of claim 1, wherein said light sensor is sensitive to electromagnetic spectrum at infrared wavelengths.

7. The optical detector of claim 1, further comprising a controller coupled to the switch and providing an on/off signals to control the switch.

8. A system for testing samples, comprising:
an excitation source applying a series of excitations pulses to the sample;
an optical sensor situated to image a desired area of the sample;
a controller providing clock signal to the excitation source and a sync signal to the optical sensor;
wherein the optical sensor comprises:
an array of light sensors, an array of charge accumulators, and a switching circuit interposed between the array of light sensors and the array of charge accumulators;
wherein the array of light sensors produces electrical current when illuminated by electromagnetic radiation, the array of charge accumulators accumulates electric charge when receiving the electrical current generated by the array of light sensors, and the switching circuit electrically isolates or connects the array of charge accumulators to the array of light sensors according to the sync signal.

9. The system of claim 8, wherein the sample is a VLSI device under test and the excitation signal comprises electrical test vector.

10. The system of claim 8, wherein the excitation signal comprises heat pulses.

11. The system of claim 8, wherein the excitation signal comprises light pulses.

12. The system of claim 8, wherein the excitation signal comprises electrical pulses.

13. The system of claim 8, wherein the sensor comprises on of MOS, InGaAs, or HgCdTe array.

14. The system of claim 8, wherein the switching circuit comprises an array of capacitors, wherein each capacitor of the array of capacitors is coupled between one respective light sensor and one respective charge accumulator.

15. The system of claim 8, wherein the switching circuit comprises an array of capacitors, wherein each capacitor of the array of capacitors is coupled between one respective sub-array of light sensors and one respective sub-array of charge accumulators.

16. The system of claim 8, further comprising a signal acquisition board receiving output signal from the charge accumulators.

17. A method for examining a sample, comprising:
applying a series of excitations pulses to the sample;
operating a light sensor array to image a selected area of the sample;
energizing a switching array so as to connect the light sensor array to a capacitor array during selected time windows at time periods between the series of excitation pulses; and,
using charge from the capacitor array to generate images of the sample.

18. The method of claim 17, wherein the charge from the capacitor array is used to generate a single image corresponding to each excitation pulse.

19. The method of claim 17, wherein the charge from the capacitor array is used to generate a series of images after each excitation pulse.

20. The method of claim 17, further comprising obtaining a clock signal and using the clock signal synchronize the series of excitation pulses and energizing the switching array.
